(19) United States
(12) Patent Application Publication
(10) Pub. No.: US 2013/0048055 A1
(43) Pub. Date: Feb. 28, 2013

(54) SEALING LAYER FOR THIN FILM PHOTOVOLTAIC DEVICES AND THEIR METHODS OF MANUFACTURE

(71) Applicants: Max William Reed, Niwot, CO (US); Troy Alan Berens, Evergreen, CO (US)

(72) Inventors: Max William Reed, Niwot, CO (US); Troy Alan Berens, Evergreen, CO (US)

(73) Assignee: PrimeStar Solar, Inc., Arvada, CO (US)

(21) Appl. No.: 13/217,409

(22) Filed: Aug. 25, 2011

(51) Int. Cl. H01L 31/048; H01L 31/0203

(52) U.S. Cl. 136/251; 438/64; 438/98; 257/E31.117

(57) ABSTRACT

A photovoltaic device is generally provided that includes a plurality of thin film layers on a glass substrate. The plurality of thin film layers define a plurality of photovoltaic cells connected in series to each other. An insulating layer is positioned on the plurality of thin film layers, and a sealing layer on the thin film layers, wherein the sealing layer comprises a polymeric material. A first lead is positioned on the insulating layer and connected to a first bus bar. An encapsulating substrate is positioned on the adhesive layer, wherein the encapsulating substrate defines a connection aperture through which the first lead extends. The sealing layer is positioned under the connection aperture defined by the encapsulating substrate to act as a moisture barrier therethrough. Methods are also generally provided for manufacturing a photovoltaic device.

### FIELD OF THE INVENTION

The subject matter disclosed herein relates generally to photovoltaic devices including an intra-laminate disk layer positioned to inhibit moisture ingress, particularly through a hole in the encapsulating substrate.

### BACKGROUND OF THE INVENTION

Thin film photovoltaic (PV) modules (also referred to as “solar panels”) based on cadmium telluride (CdTe) paired with cadmium sulfide (CdS) as the photo-reactive components are gaining wide acceptance and interest in the industry. CdTe is a semiconductor material having characteristics particularly suited for conversion of solar energy to electricity. The junction of the n-type layer and the p-type layer is generally responsible for the generation of electric potential and electric current when the CdTe PV module is exposed to light energy, such as sunlight. Specifically, the cadmium telluride (CdTe) layer and the cadmium sulfide (CdS) form a p-n heterojunction, where the CdTe layer acts as a p-type layer (i.e., a positive, electron accepting layer) and the CdS layer acts as a n-type layer (i.e., a negative, electron donating layer).

A transparent conductive oxide (“TCO”) layer is commonly used between the window glass and the junction forming layers. This TCO layer provides the front electrical contact on one side of the device and is used to collect and carry the electrical charge produced by the cell. Conversely, a back contact layer is provided on the opposite side of the junction forming layers and is used as the opposite contact of the cell. This back contact layer is adjacent to the p-type layer, such as the cadmium telluride layer in a CdTe PV device.

An encapsulating substrate is positioned on the opposite side of the device to encase the thin film layers between the window glass and the encapsulating substrate. The encapsulating substrate typically contains a hole that enables connection of the photovoltaic device to lead wires for the collection of the DC electricity created by the PV device. However, since PV devices are typically used outside, the PV devices are subjected to varying environmental conditions and exposed to humidity, dew, rain, and other moisture vapor exposure. The hole in the encapsulating substrate can be particularly susceptible to moisture vapor ingress into the device. Such moisture vapor can reduce the efficiency of the PV device and significantly shorten its effective lifespan.

As such, a need exists to inhibit and prevent moisture vapor ingress into the PV device, particularly at the hole in the encapsulating substrate.

### BRIEF DESCRIPTION OF THE INVENTION

Aspects and advantages of the invention will be set forth in part in the following description, or may be obvious from the description, or may be learned through practice of the invention.

A photovoltaic device is generally provided that includes a plurality of thin film layers on a glass substrate. The plurality of thin film layers define a plurality of photovoltaic cells connected in series to each other. An insulating layer is positioned on the plurality of thin film layers, and a sealing layer on the thin film layers, wherein the sealing layer comprises a polymeric material. A first lead is positioned on the insulating layer and connected to a first bus bar. An encapsulating substrate is positioned on the adhesive layer, wherein the encapsulating substrate defines a connection aperture through which the first lead extends. The sealing layer is positioned under the connection aperture defined by the encapsulating substrate to act as a moisture barrier therethrough.

Methods are also generally provided for manufacturing a photovoltaic device. In one embodiment, a sealing layer can be applied on an insulating material, wherein the insulating layer is on a plurality of thin film layers overlying a substrate. A first lead can then be applied over the insulating layer and the sealing layer, and a first sealing strip can be applied over a portion of the first lead. An encapsulating substrate can be attached over the thin film layers, wherein the encapsulating substrate defines a connection aperture through which the first lead extends. The encapsulating substrate can be laminated at a lamination temperature sufficient to thermally bond the sealing layer to the first sealing strip.

In one particular embodiment, the method of manufacturing a photovoltaic device can include applying a sealing layer on an insulating layer, wherein the insulating layer is on a plurality of thin film layers overlying a substrate. A first lead and a second lead can then be applied over the insulating layer and the sealing layer. A first sealing strip can be applied over a portion of the first lead, and a second sealing strip can be applied over a portion of the second lead. An encapsulating substrate can then be attached over the thin film layers, wherein the encapsulating substrate defines a connection aperture through which the first lead and the second lead extend. The encapsulating substrate can be laminated at a lamination temperature sufficient to thermally bond the sealing layer to the first sealing strip and the second sealing strip.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWING

A full and enabling disclosure of the present invention, including the best mode thereof, directed to one of ordinary skill in the art, is set forth in the specification, which makes reference to the appended figures, in which:

FIG. 1 shows a cross-sectional view of an exemplary thin film photovoltaic device according to one embodiment;

FIG. 2 shows a cross-sectional view of the exemplary thin film photovoltaic device of FIG. 1 having an encapsulating substrate attached;

FIG. 3 shows a cross-sectional view of the exemplary thin film photovoltaic device of FIG. 1 having a junction box attached to the encapsulating substrate at its connection aperture;

FIG. 4 shows a cross-sectional view of another exemplary thin film photovoltaic device;

FIG. 5 shows a top view of an exemplary thin film photovoltaic device defining a plurality of cells;

FIG. 6 shows a top view of the exemplary photovoltaic device of FIG. 5 having an insulating layer on the photovoltaic cells;

FIG. 7 shows a top view of the exemplary photovoltaic device of FIG. 6 with an optional intra-laminate disk layer;

FIG. 8 shows a top view of the exemplary photovoltaic device of either FIG. 6 or 7 with a sealing layer;

FIG. 9, shows a top view of the exemplary photovoltaic device of FIG. 8 with a conductive strip applied on the insulating strip;

FIG. 10 shows a top view of the exemplary photovoltaic device of FIG. 9 with the conductive strip severed and a pair of sealing strips positioned thereon;

FIG. 11 shows a top view of the exemplary photovoltaic device of FIG. 9 with the conductive strip severed and a sealing ring positioned thereon; and,

FIG. 12 shows a flow diagram of an exemplary method of forming the photovoltaic device of FIG. 3 or 4.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers unless otherwise specifically noted. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “gm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

A thin film photovoltaic device is generally provided having a sealing layer positioned to inhibit moisture vapor ingress, particularly through a hole in the encapsulating substrate utilized to collect the DC electricity generated by the PV device. This added hindrance of moisture vapor ingress into the PV device can increase the useful life of the PV device.

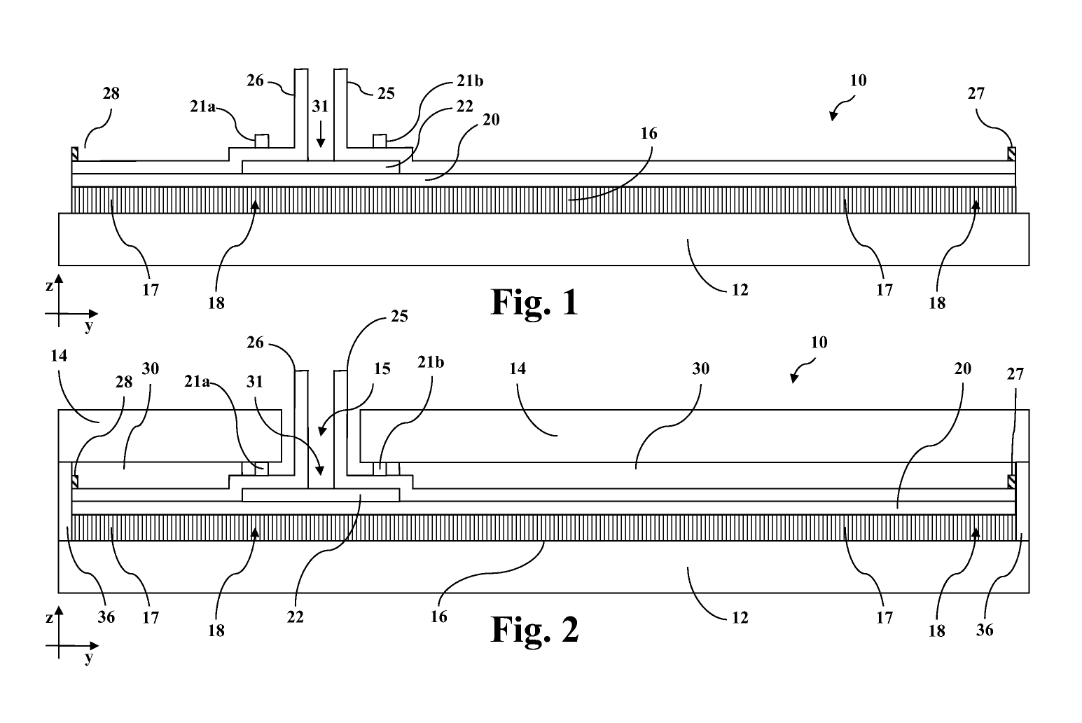

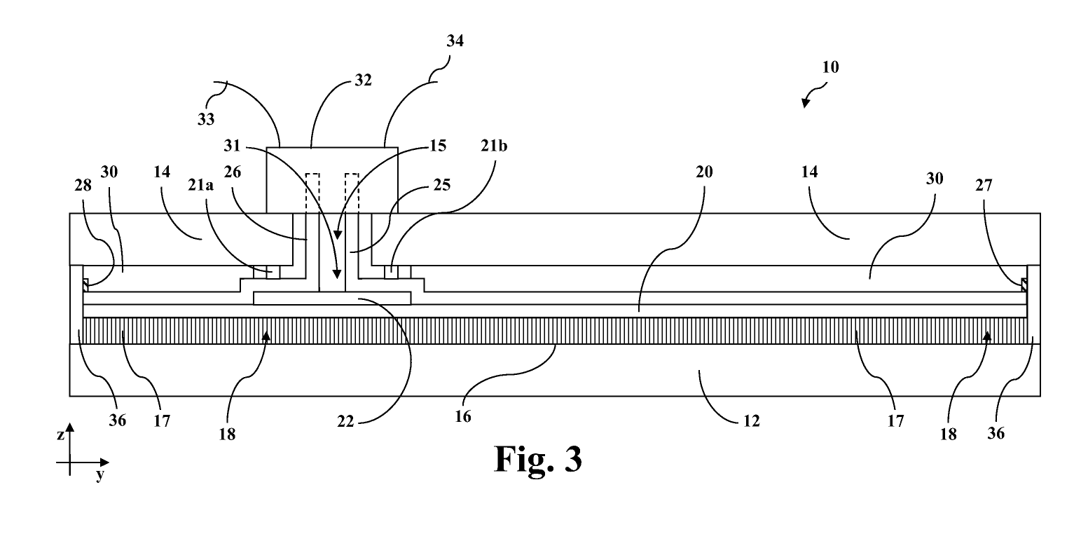

FIGS. 1-3 show a cross-sectional view of an exemplary thin film photovoltaic device 10. The photovoltaic device 10 generally includes a glass substrate 12 oppositely positioned from an encapsulating substrate 14. In this embodiment, the glass 12 can be referred to as a “superstrate,” as it is the substrate on which the subsequent layers are formed even though it faces upward to the radiation source (e.g., the sun) when the photovoltaic device 10 is in use. The top sheet of glass 12 can be a high-transmission glass (e.g., high transmission borosilicate glass), low-iron float glass, or other highly transparent glass material. The glass is generally thick enough (e.g., from about 0.5 mm to about 10 mm thick) to provide support for the subsequent film layers, and is substantially flat to provide a good surface for forming the subsequent film layers. In one embodiment, the glass 12 can be a low iron float glass containing less than about 0.015% by weight iron (Fe), and may have a transmissiveness of about 0.9 or greater in the spectrum of interest (e.g., wavelengths from about 300 nm to about 900 nm). In another embodiment, a high strain-point glass, such as borosilicate glass, may be utilized so as to better withstand high temperature processing.

The encapsulating substrate 14 defines a connection aperture 15 providing access to the underlying components to collect the DC electricity generated by the photovoltaic device 10. In one particular embodiment, the encapsulating substrate 14 is a glass substrate.

A plurality of thin film layers 16 are positioned on the glass substrate 12. The plurality of thin film layers 16 define individual photovoltaic cells 17 separated by scribes 18. The individual photovoltaic cells 17 are electrically connected together in series. In one particular embodiment, the plurality of thin film layers can include a transparent conductive oxide layer (e.g., cadmium stannate or stoichiometric variation of cadmium, tin, and oxygen; indium tin oxide, etc.) on the glass substrate 12, a resistive transparent buffer layer (e.g., a combination of zinc oxide and tin oxide, etc.) on the transparent conductive oxide layer, an n-type layer on the resistive transparent buffer layer, a p-type layer on the n-type layer, and a back contact on the p-type layer. In one particular embodiment, the n-type layer can include cadmium sulfide (i.e., a cadmium sulfide thin film layer), and the p-type layer can include cadmium telluride (i.e., a cadmium telluride thin film layer). Other thin film layers may also be present in the film stack. Generally, the back contact defines the exposed surface of the thin film layers 16, and serves as an electrical contact of the thin film layers opposite the front contact defined by the transparent conductive oxide layer.

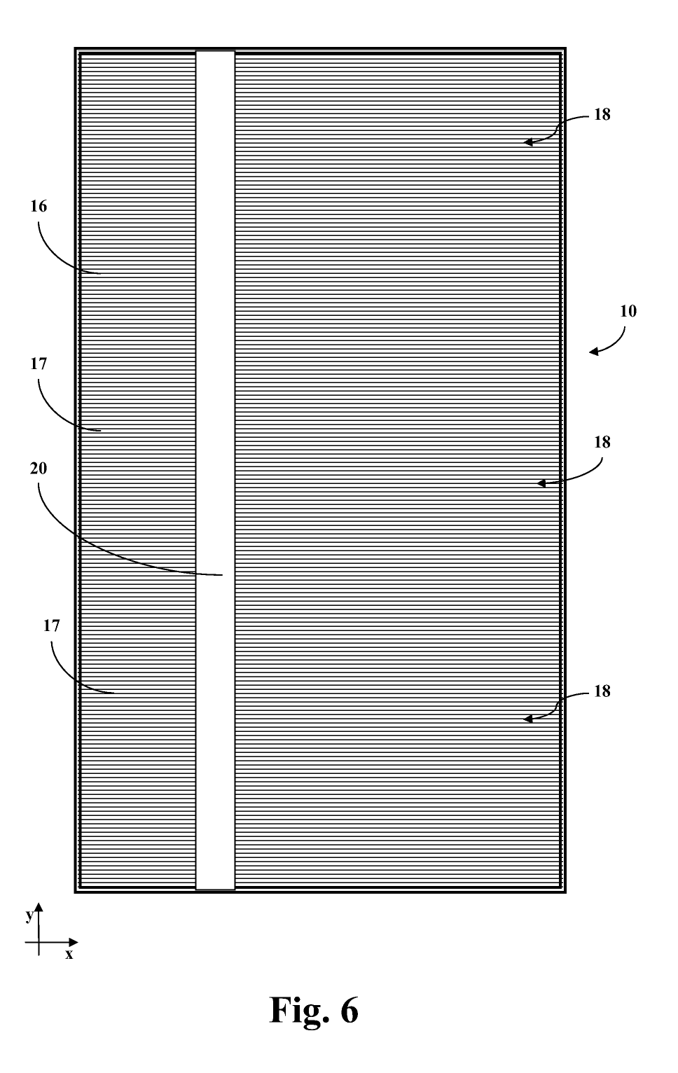

For instance, FIG. 5 generally shows a top view of an exemplary thin film photovoltaic device 10 defining a plurality of photovoltaic cells 17 separated by scribes 18. The scribes 18 can be, in one embodiment, substantially parallel to each other such that the photovoltaic cells 17 are substantially the same size. As shown, each of the scribes 18 is generally oriented in the x-direction. However, any suitable cell geometry may be utilized.

An insulating layer 20 is provided on the thin film layers 16 to isolate the back contact of the thin film layers 16 from the conductive strip 24. The insulating layer 20 generally includes an insulating material that can prevent electrical conductivity therethrough. Any suitable material can be used to produce the insulating layer 20. In one embodiment, the insulating layer 20 can be an insulating polymeric film coated on both surfaces with an adhesive coating. The adhesive coating can allow for adhesion of the insulating layer 20 to the underlying thin film layers 16 and for the adhesion of the conductive strip 24 to the insulating layer 20. For example, the insulating layer 20 can include a polymeric film of polyethylene terephthalate (PET) having an adhesive coating on either surface. The adhesive coating can be, for example, an acrylic adhesive, such as a pressure sensitive acrylic adhesive.

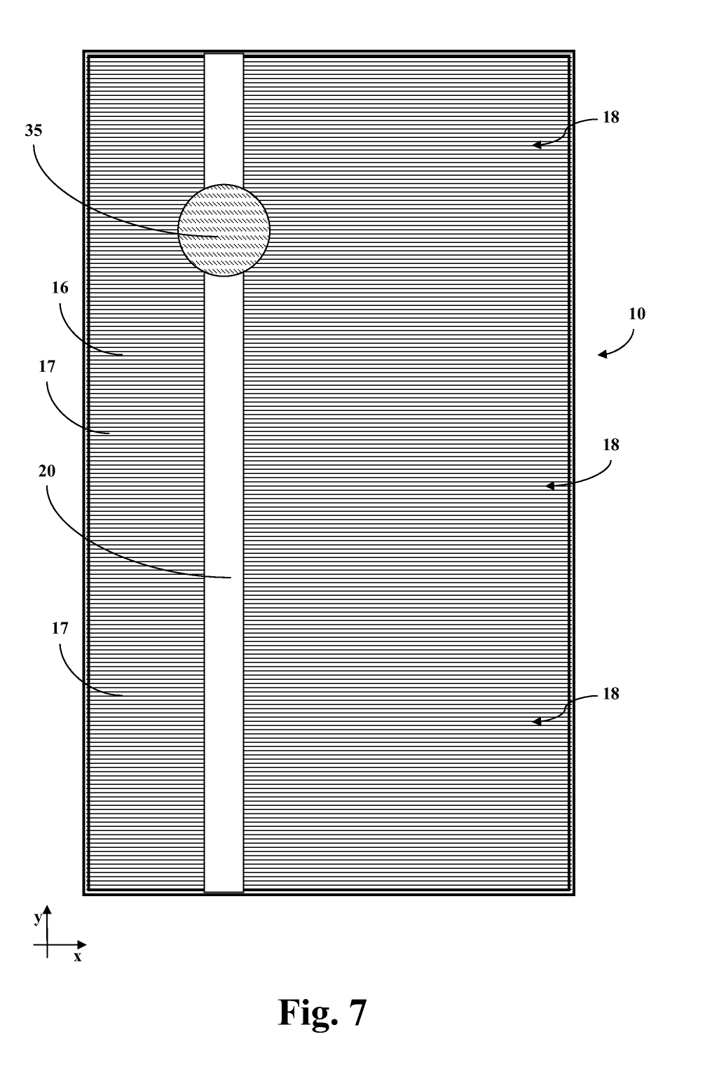

In one particular embodiment, the insulating layer 20 is a strip of insulating material generally oriented in a direction perpendicular to the orientation of the scribes 18. For example, as shown in FIG. 6, the insulating layer 20 can be generally oriented in the y-direction that is perpendicular to the orientation of the scribes 18 in the x-direction. The insulating layer 20 can have a thickness in the z-direction suitable to prevent electrical conductivity from the underlying thin film layers, particularly the back contact, to any subsequently applied layers. In one particular embodiment, the insulating layer 20 can prevent electrically conductivity between the thin film layers 16 and the conductive strip 24.

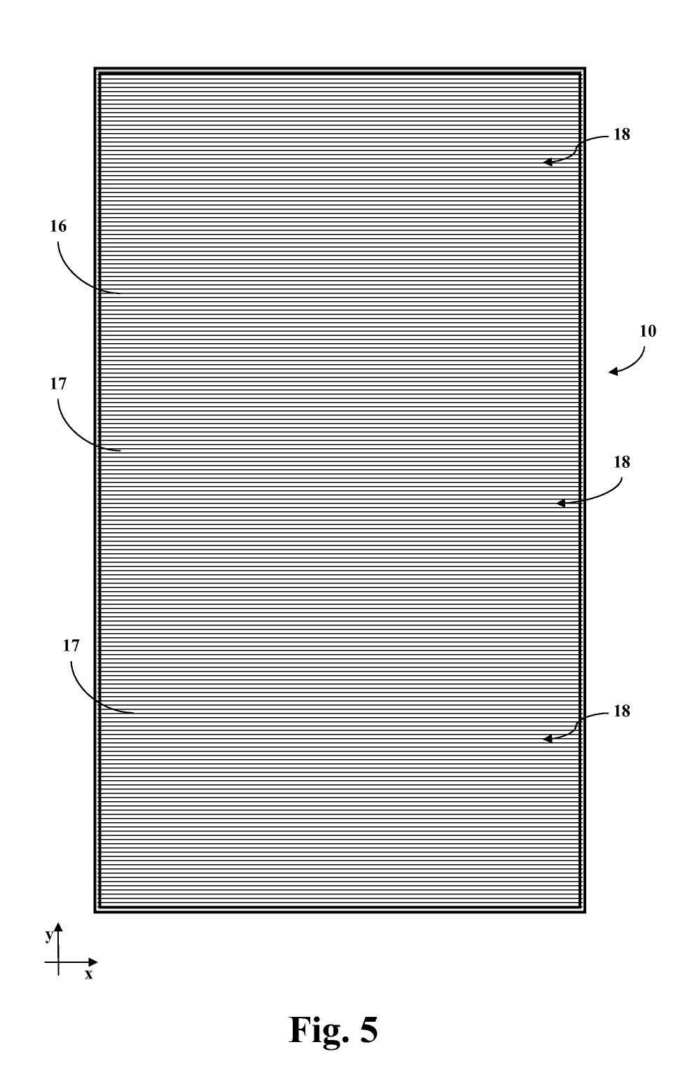

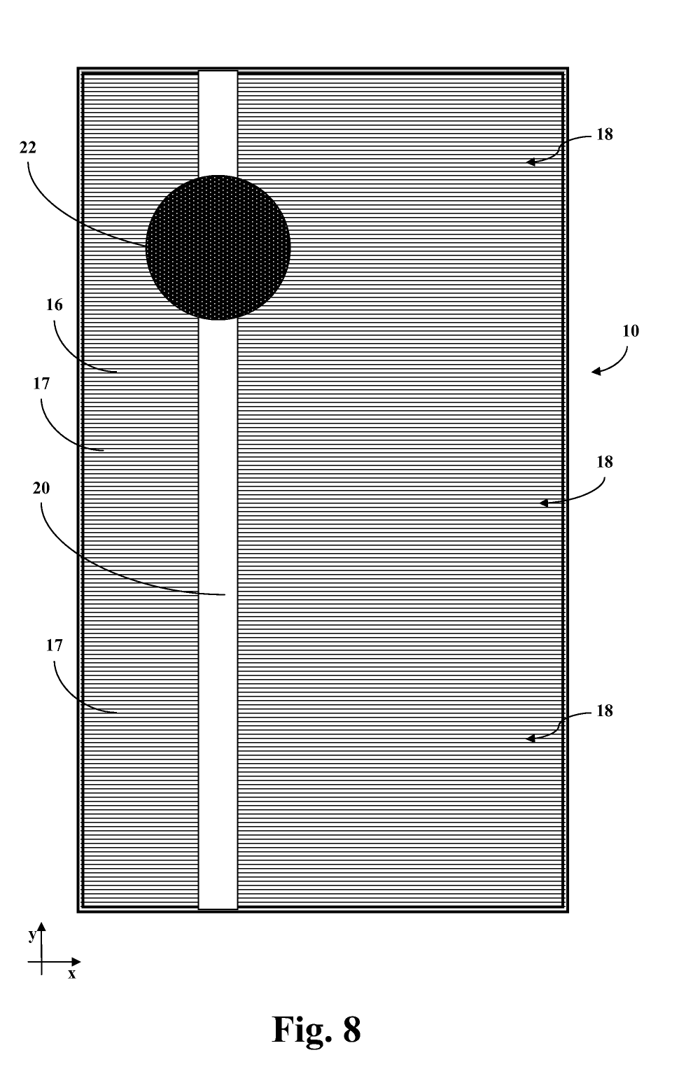

Optionally, an intra-laminate disk layer 35 can be positioned on the insulating layer 20 over an area of the thin film layers 16 to be exposed by the connection aperture 15 of the encapsulating substrate 14, as shown in FIGS. 4 and 7. For example, the intra-laminate disk layer 35 can extend over a protected area (as defined in the x- and y-directions on the surface of the thin film layers 16) that is larger than the connection aperture 15 defined by the encapsulating substrate 14 and/or that is that is larger than the adhesive gap 31 defined by the adhesive layer 30.

When present, the intra-laminate disk layer 35 can define a substantially circular disk in the x, y plane. This shape can be particularly useful when both the adhesive gap 31 defined in the adhesive layer 30 and the connection aperture 15 in the encapsulating substrate 14 have the same shape in the x, y plane (e.g., circular, square, rectangular, etc.). As such, the intra-laminate disk layer 35 can be substantially centered with respect to the adhesive gap 31 defined by the adhesive layer 30 and to the connection aperture 15 defined by the encapsulating substrate 14. Also, with this configuration, the disk diameter of the intra-laminate disk layer 35 can be larger than the gap diameter defined by the adhesive gap 31 and/or the aperture diameter defined by the connection aperture 15. For instance, the disk diameter can be at about 5% larger to about 200% larger than the gap diameter and/or the connection diameter, such as about 10% larger to about 100% larger. However, other sizes and shapes may be used as desired. In certain embodiments, the intra-laminate disk layer can define a thickness, in the z-direction, of about 50 μm to about 400 μm. If too thick, however, the intra-laminate disk layer 35 could lead to de-lamination of the device 10.

The intra-laminate disk layer 35 can, in one embodiment, be a polymeric film. In one particular embodiment, the film can be a polymeric film, including polymers such as polyethylene, polypropylene, polyethylene terephthalate (PET), ethylene-vinyl acetate copolymer, or copolymers or mixtures thereof. Alternatively, the intra-laminate disk layer 35 can be a sheet of thin glass, e.g., having a thickness of about 0.02 mm to about 0.25 mm (e.g., 0.04 mm to 0.15 mm). When constructed of glass, the intra-laminate disk layer 35 can provide excellent barrier properties to moisture along with providing some structural support to the device 10. It is to be understood that the intra-laminate disk layer 35 could yet instead be in the form of a laminated glass disk, with a glass sheet having a laminate layer thereon being made, for example, of a polymeric film as per above. Such a laminated glass disk could provide the adhesion characteristics of the polymeric film and the barrier properties of the glass, and may also play a role in making the hole region more resistant to hail impact, especially if it is comprised of glass.

The intra-laminate disk layer 35 can be, in one particular embodiment, applied after the insulating layer 20, such as shown in FIGS. 6-7, to result in the embodiment of FIG. 4, where the intra-laminate disk layer 35 is positioned between the insulating layer 20 and the sealing layer 22.

In one embodiment, the sealing layer 22 can be utilized to hold the intra-laminate disk layer 35 in place in the finished PV device 10 by providing the intra-laminate disk in a smaller size in the x, y plane (e.g., a smaller diameter) than the sealing layer 22, such that the sealing layer 22 bonds the edges of the intra-laminate disk layer 35 to the thin film layers 16. However, the intra-laminate disk layer 35, in one embodiment, can be constructed of a film having a polymeric coating on one or both surfaces. The polymeric coating can include a hydrophobic polymer configured to inhibit moisture ingress through the intra-laminate disk layer 35 and/or around the intra-laminate disk layer 35. In addition, the polymeric coating can help adhere the intra-laminate disk layer 35 to the underlying layers (e.g., the thin film layers 16) and subsequently applied layers (e.g., the adhesive layer 30). In one particular embodiment, the polymeric coating can include a material similar to the adhesive layer 30 in the device (e.g., an ethylene-vinyl acetate copolymer).

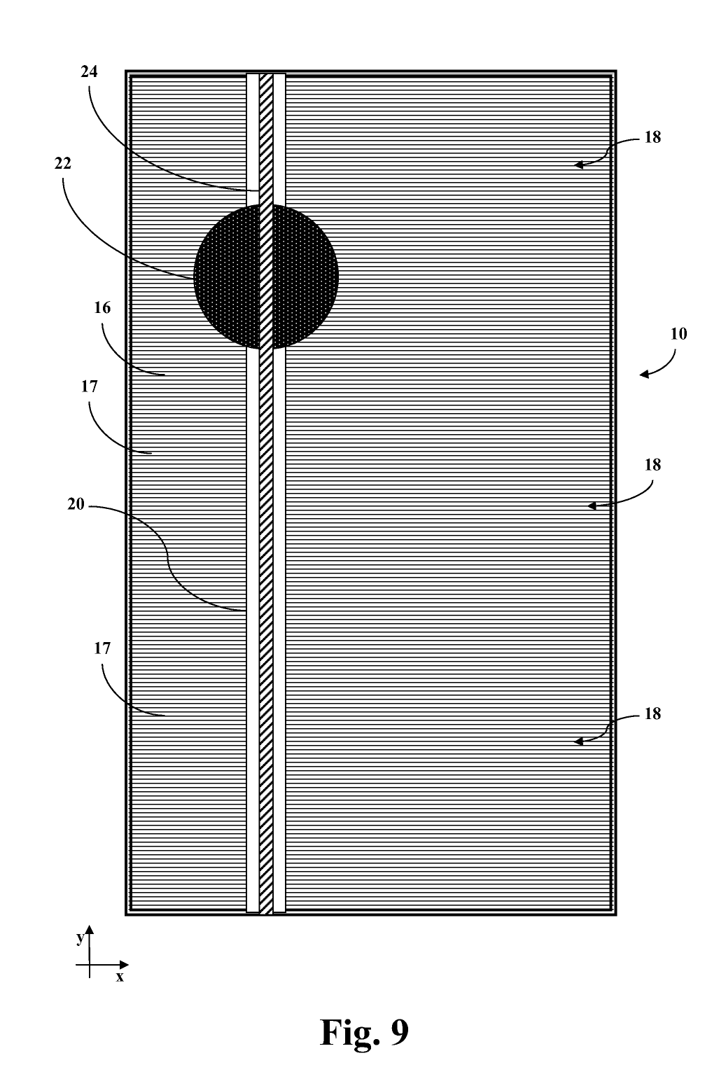

A sealing layer 22 can then be applied on the thin film layers 16 and the insulating layer 20 (and optional intra-laminate disk layer 35, if present), as shown in FIG. 8. The sealing layer can be positioned where the connection aperture 15 of the encapsulating substrate 14 will be located on the device 10, as shown in FIGS. 1-4.

The composition of the sealing layer 22 (e.g., a synthetic polymeric material, as discussed below) can be selected such that the sealing layer 22 has a moisture vapor transmission rate that is 0.5 g/m²/24 hr or less (e.g., 0.1 g/m²/24 hr or less, such as 0.1 g/m²/24 hr to about 0.001 g/m²/24 hr). As used herein, the “moisture vapor transmission rate” is determined according to the test method of ASTM F1249 at a 0.080″ thickness. As such, the sealing layer 22 can form a moisture barrier between the connection aperture 15 in the encapsulating substrate 14 and the thin film layers 16 and define a protected area thereon.

In one embodiment, the sealing layer 22 can be sized to be larger than the connection aperture 15 defined by the encapsulating substrate 14 (e.g., if circular, the sealing layer 22 can have a diameter that is larger than the diameter of the connection aperture 15). In this embodiment, the sealing layer 22 can not only form a moisture barrier between the protected area of the thin film layers 16 and the connection aperture 15, but also can help adhere the encapsulating glass 14 to the device 10.

In one particular embodiment, the sealing layer 22 can include a synthetic polymeric material. The synthetic polymeric material can, in one embodiment, melt at the lamination temperature, reached when the encapsulating substrate 14 is laminated to the substrate 12, such that the synthetic polymeric material melts and/or otherwise conforms and adheres to form a protected area on the thin film layers 16 where the connection aperture 15 is located on the device 10. For instance, the synthetic polymeric material can melt at laminations temperatures of about 120° C. to about 160° C.

The synthetic polymeric material can be selected for its moisture barrier properties and its adhesion characteristics, especially between the encapsulating substrate 14 (e.g., a glass) and the back contact layer(s) of the thin film layers 16. For example, the synthetic polymeric material can include, but is not limited to, a butyl rubber or other rubber material. Though the exact chemistry of the butyl rubber can be tweaked as desired, most butyl rubbers are a copolymer of isobutylene with isoprene (e.g. produced by polymerization of about 98% of isobutylene with about 2% of isoprene). One particularly suitable synthetic polymeric material for use in the sealing layer 22 is available commercially under the name HelioSeal® PVS 101 from ADCO Products, Inc. (Michigan Center, Mich.).

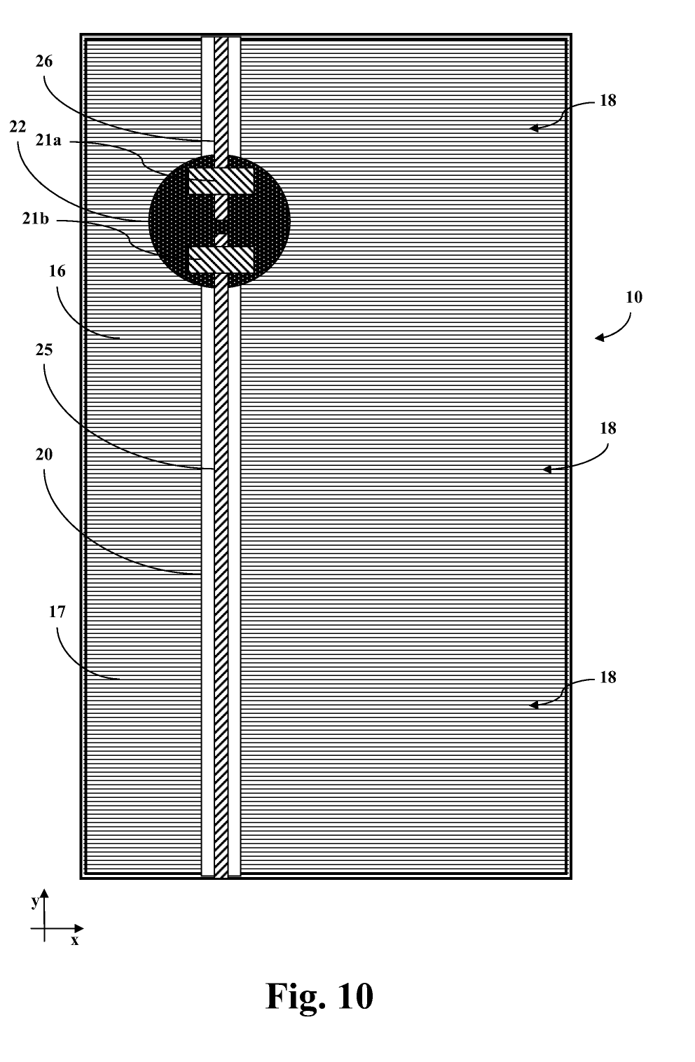

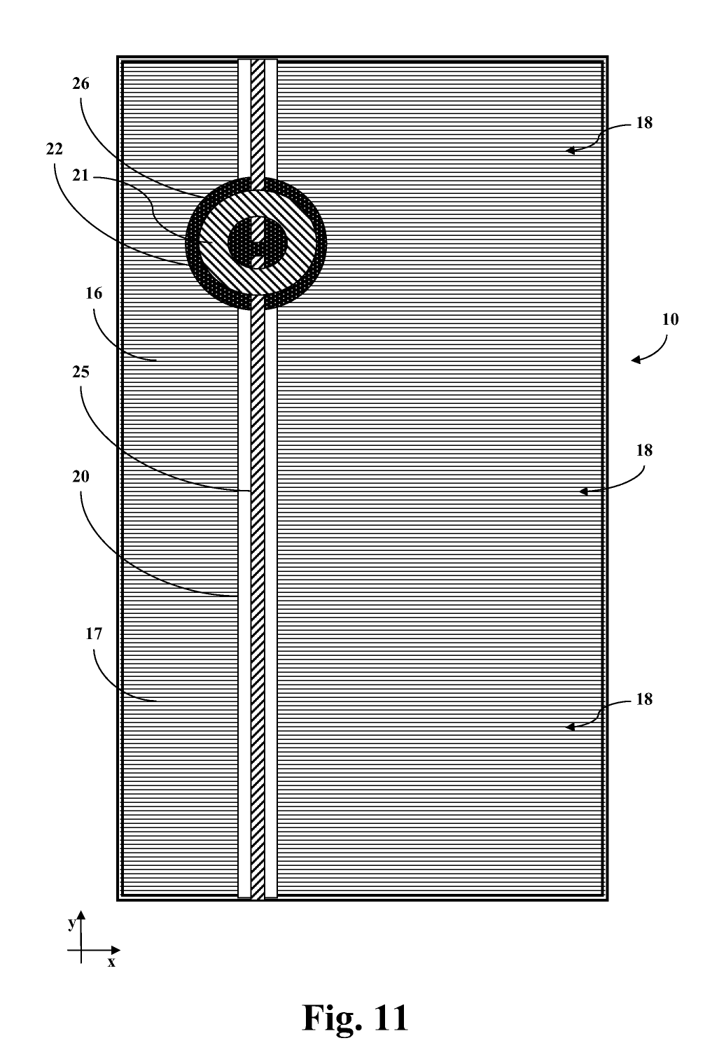

The conductive strip 24, in one embodiment, can be applied as a continuous strip over the insulating layer 20 and the sealing layer 22, as shown in FIG. 9. Then, the continuous strip can then be severed to produce a first lead 25 and a second lead 26, as shown in FIG. 10. The conductive strip 24 can be constructed from any suitable material. In one particular embodiment, the conductive strip 24 is a strip of metal foil. For example, the metal foil can include a conductive metal.

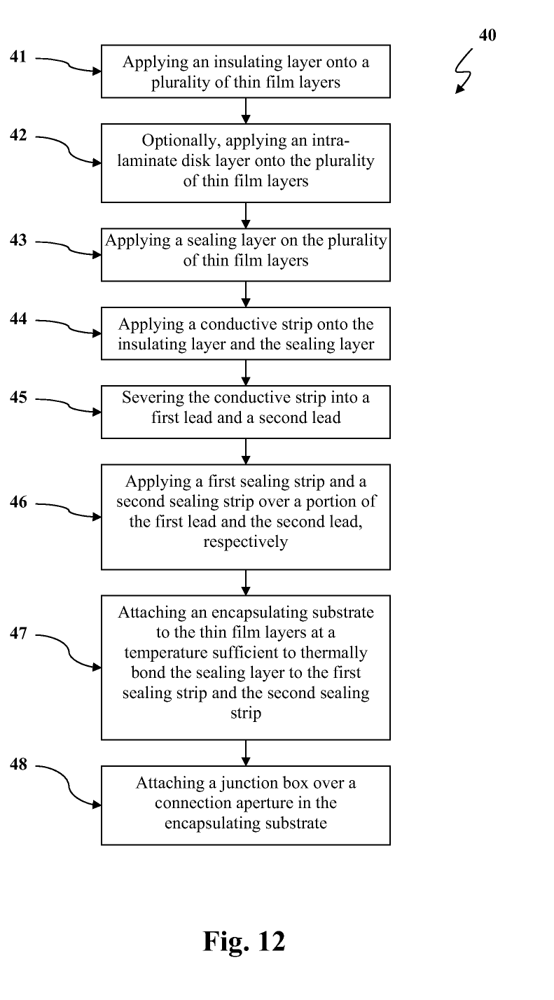

A first sealing strip 21a and a second sealing strip 21b can extend over a portion of the first lead 25 and the second lead 26, respectively, as shown in FIG. 10. The sealing strips 21a, 21b can be seen in the cross-section shown in FIGS. 1-4, but may be connected to each other, such as in the form of a ring, as shown in FIG. 11. No matter their exact configuration, the sealing layer 22 can be thermally bonded to the first sealing strip 21a and the second sealing strip 21b to surround the first lead 25 and second lead 26, respectively. Thus, the first sealing strip 21a and the sealing layer 22 can form a circumferential moisture barrier about the first lead 25 to inhibit moisture ingress along the first lead 25 and into the device 10. Likewise, the second sealing strip 21b and the sealing layer 22 can form a circumferential moisture barrier about the second lead 26 to inhibit moisture ingress along the second lead 26 and into the device 10.

The sealing strips 21a, 21b can have any composition as discussed above with respect to the sealing layer 22. Although the composition of the sealing strips 21a, 21b may be selected independently from the each other and/or the sealing layer 22, in one embodiment, the sealing strips 21a, 21b can have the same composition as the sealing layer 22 (e.g., a butyl rubber).

Bus bars 27, 28, as shown in FIGS. 1-4, can be attached over opposite ends of the photovoltaic device 10 to connect the photovoltaic cells 17 of the thin film layers 16 to the first lead 25 and second lead 26. For example, the first bus bar 27 can overlie the photovoltaic cell 17 positioned at the first end of the photovoltaic device 10, while the second bus bar 28 overlies the photovoltaic cell 17 at the second end of the photovoltaic device 10 opposite the first end. Since the photovoltaic cells 17 are connected to each other in series, the bus bars 27, 28 can serve as opposite electrical connections (e.g., positive and negative) on the photovoltaic device 10. Generally, the conductive strip 24 electrically connects the opposite electrical bus bars 27, 28 to the first lead 25 and the second lead 26.

The encapsulating substrate 14 can be adhered to the photovoltaic device 10 via an adhesive layer 30 and the sealing layer 22 and the sealing strips 21a, 21b (or ring 21). The adhesive layer 30 is generally positioned over the sealing strips 21a, 21b, leads 25, 26, sealing layer 22, intra-laminate disk layer 35 (when present), insulating layer 20, and any remaining exposed areas of the thin film layers 16. The adhesive layer 30 generally defines an adhesive gap 31 that generally corresponds to the connection aperture 15 defined by the encapsulating substrate 14. As such, the first lead 25 and second lead 26 can extend through the adhesive gap 31. The adhesive layer 30 can generally protect the thin film layers 16 and attach the encapsulating substrate 14 to the device 10. The adhesive layer 30 can be constructed from ethylene vinyl acetate (EVA), polyvinyl butyral (PVB), silicone based adhesives, or other adhesives which are configured to prevent moisture from penetrating the device.

In one particular embodiment, the adhesive layer 30 can have an adhesive gap 31 that is larger than the connection aperture 15 in the encapsulating substrate 14, to allow the sealing layer 22 and sealing strips 21a, b (or ring 21) to form a seal around the connection aperture 15. This configuration can allow for the sealing layer 22 and sealing strips 21a, 21b to bond directly to the encapsulating substrate 14 as shown in FIGS. 1-4. As such, in one particular embodiment, the adhesive gap 31 can be substantially the same size and shape as the sealing layer 22, and can be positioned so as to be mated when laminated.

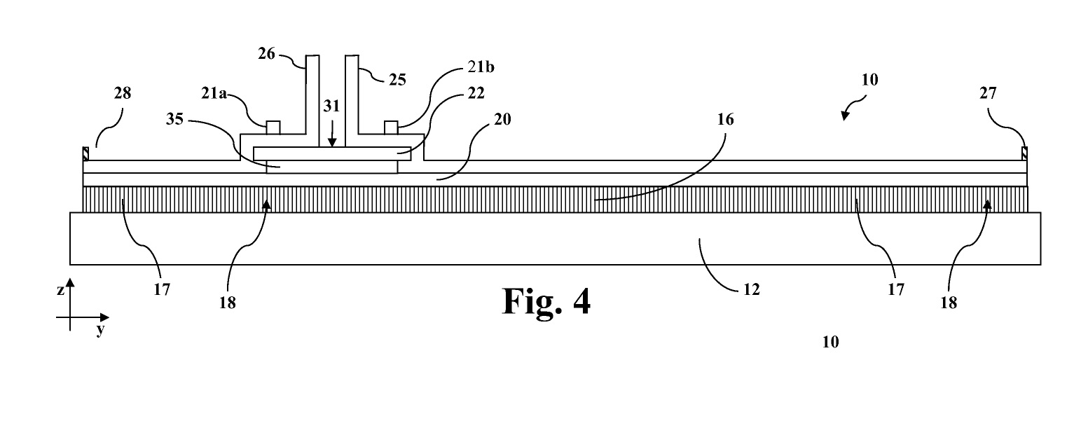

Finally, a junction box 32 can be attached to the device 10 and positioned to cover the connection aperture 15. FIG. 3 shows a junction box 32 configured to electrically connect the photovoltaic device 10 by completing the DC circuit. The junction box 32 can then provide a positive lead wire 33 and a negative lead wire 34 for further collection of the DC electricity produced by the photovoltaic device 10.

Edge sealing layers 36 can be applied around the edges of the device 10 to seal the substrate 12 to the encapsulating substrate 14 along each edge. The edge sealing layers 36 can be constructed and applied as discussed above with respect to the sealing layer 22. In one particular embodiment, the edge sealing layers 36 can have substantially the same composition as the sealing layer 22 and/or the sealing strips 21.

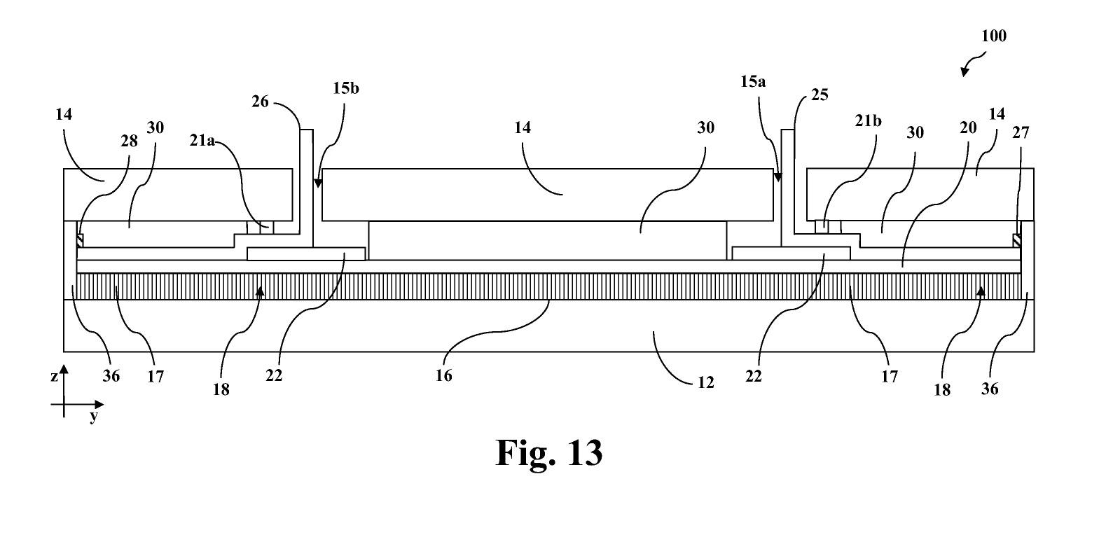

FIG. 12 generally shows a flow diagram of one exemplary method 40 for construction of the exemplary photovoltaic devices 10 of FIGS. 1-4. According to this method, an insulating layer (e.g., an insulating strip) is applied on plurality of thin film layers at 41. Optionally, an intra-laminate disk layer is applied on the plurality of thin film layers at 42. A sealing layer can be applied on the plurality of thin film layers (e.g., over a portion of the insulating layer and intra-laminate disk layer, if present) at 43. A conductive strip can then be applied on the insulating layer at 44, and severed into a first lead and a second lead at 45. A first sealing strip and a second sealing strip can be applied over a portion of the first lead and the second lead, respectively, at 46. For instance, steps 41-46 of method 40 are exemplified sequentially in FIGS. 5-11.

Method 40 also includes, at 47, attaching an encapsulating substrate (e.g., defining a connection aperture) to the thin film layers at a temperature sufficient to thermally bond the sealing layer to the first sealing strip and second sealing strip. A junction box can be attached over the connection aperture at 48.

FIG. 13 shows another embodiment of an exemplary photovoltaic device 100 having a monopole-type configuration where each lead 25, 26 exits its on aperture 15a, 15b, respectively, in the encapsulating substrate 14.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A photovoltaic device, comprising:
a glass substrate;
a plurality of thin film layers on the glass substrate, wherein the plurality of thin film layers define a plurality of photovoltaic cells connected in series to each other;
an insulating layer on the plurality of thin film layers;
a sealing layer on the thin film layers, wherein the sealing layer comprises a polymeric material;
a first lead on the insulating layer and connected to a first bus bar; and,
an encapsulating substrate on the adhesive layer, wherein the encapsulating substrate defines a connection aperture through which the first lead extends,
wherein the sealing layer is positioned under the connection aperture defined by the encapsulating substrate to act as a moisture barrier therethrough.

2. The device of claim 1, further comprising:
a first sealing strip extending over a portion of the first lead;

3. The device of claim 1, further comprising:
a second lead on the insulating layer connected to a second bus bar; and
a second sealing strip extending over the a portion of the second lead.

4. The device of claim 3, wherein the second lead extends through the connection aperture defined by the encapsulating substrate.

5. The device of claim 4, wherein the first sealing strip and the second sealing strip are connected to form a sealing ring.

6. The device of claim 1, wherein the sealing layer is thermally bonded to the first sealing strip to surround the first lead.

7. The device of claim 1, wherein the sealing layer comprises a synthetic polymeric material.

8. The device of claim 7, wherein the sealing layer has a moisture vapor transmission rate of 0.5 g/m²/24 hr or less.

9. The device of claim 1, wherein the synthetic polymeric material comprises a butyl rubber.

10. The device of claim 1, wherein the insulating layer is positioned between the thin film layers and the sealing layer.

11. The device of claim 1, further comprising:
an intra-laminate disk layer positioned between the thin film layers and the sealing layer, wherein the intra-laminate disk layer is positioned between the insulating layer and the sealing layer.

12. The device of claim 1, wherein the sealing layer extends over a protected area on the thin film layers that is larger than the connection aperture defined by the encapsulating substrate.

13. The device of claim 1, further comprising:
an adhesive layer positioned between the encapsulating substrate and the thin film layers, wherein the adhesive layer defines an adhesive gap, and wherein the sealing layer extends over a protected area on the thin film layers that is larger than the adhesive gap defined by the adhesive layer.

14. The device of claim 1, wherein the sealing layer is substantially centered with respect to the connection aperture defined by the encapsulating substrate.

15. The device of claim 1, wherein the sealing layer defines a thickness of about 50 μm to about 400 μm.

16. The device of claim 1, wherein the plurality of thin film layers comprises:
a transparent conductive oxide layer on the glass substrate;
a resistive transparent buffer layer on the transparent conductive oxide layer;
an n-type window layer on the resistive transparent buffer layer, wherein the n-type window layer comprises cadmium sulfide;
an absorber layer on the n-type window layer, wherein the absorber layer comprises cadmium telluride; and,
a back contact on the absorber layer.

17. A method of manufacturing a photovoltaic device, the method comprising:
applying a sealing layer on an insulating layer, wherein the insulating layer is on a plurality of thin film layers overlying a substrate;
applying a first lead over the insulating layer and the sealing layer;
applying a first sealing strip over a portion of the first lead;
attaching an encapsulating substrate over the thin film layers, wherein the encapsulating substrate defines a connection aperture through which the first lead extends; and,
laminating the encapsulating substrate at a lamination temperature sufficient to thermally bond the sealing layer to the first sealing strip.

18. The method of claim 17, further comprising:
applying a second lead over the insulating layer and a second sealing layer; and
applying a second sealing strip over a portion of the second lead,
wherein the encapsulating substrate is attached over the thin film layers such that the second lead extends through a second connection aperture defined in the encapsulating substrate and laminated sufficient to thermally bond the sealing layer to the second sealing strip.

19. A method of manufacturing a photovoltaic device, the method comprising:
applying a sealing layer on an insulating layer, wherein the insulating layer is on a plurality of thin film layers overlying a substrate;
applying a first lead and a second lead over the insulating layer and the sealing layer;
applying a first sealing strip over a portion of the first lead;
applying a second sealing strip over a portion of the second lead;
attaching an encapsulating substrate over the thin film layers, wherein the encapsulating substrate defines a connection aperture through which the first lead and the second lead extend; and,
laminating the encapsulating substrate at a lamination temperature sufficient to thermally bond the sealing layer to the first sealing strip and the second sealing strip.

20. The method of claim 19, wherein the first sealing strip and the second sealing strip are interconnected to form a sealing ring.
